(19) United States
(12) Patent Application Publication
(10) Pub. No.: US 2010/0140775 A1
(43) Pub. Date: Jun. 10, 2010

(54) SEMICONDUCTOR DEVICE AND METHOD FOR MANUFACTURING THE SAME

(76) Inventor: Oh Jin Jung, Gyeonggi-do (KR)

Correspondence Address: SALIWANCHIK LLOYD & SALIWANCHIK;A PROFESSIONAL ASSOCIATION, PO Box 142950, GAINESVILLE, FL, 32614, US

(21) Appl. No.: 12/630,188

(22) Filed: Dec. 3, 2009

(30) Foreign Application Priority Data
Dec. 10, 2008 (KR) 10-2008-0125508

(51) Int. Cl. H01L 23/535; H01L 23/48; H01L 21/768

(52) U.S. Cl. 257/686; 257/774; 438/627; 257/698; 438/680; 438/637; 257/E21.575; 257/E23.168; 257/E23.011; 977/762

(57) ABSTRACT

Provided are a semiconductor device and a method for manufacturing the same. The semiconductor device comprises a circuit layer, a metal interconnection layer, and a deep via. The circuit layer is formed on a semiconductor substrate. The metal interconnection layer is formed on the circuit layer. The metal interconnection layer comprises a metal interconnection connected to the circuit layer. The deep via penetrates through the semiconductor substrate and the metal interconnection layer. The deep via comprises a laser-annealed crystalline silicon.

### CROSS-REFERENCE TO RELATED APPLICATION

This application claims the benefit under 35 U.S.C. §119 of Korean Patent Application No. 10-2008-0125508, filed Dec. 10, 2008, which is hereby incorporated by reference in its entirety.

### BACKGROUND

The present disclosure relates to a semiconductor device and a method for manufacturing the same.

Recently, studies of methods for manufacturing a semiconductor device through lamination of various semiconductor chips as well as technologies of manufacturing fine circuits in a semiconductor process are being actively conducted to reproduce complex circuit structures in recent semiconductor technologies. A method of stacking various kinds of semiconductor devices in a chip or wafer state and connecting them through vias is named System-In-Package (SIP). Since various chips are vertically stacked by the SIP technology, the SIP technology has an advantage of miniaturization of a semiconductor device. The core of the SIP technology is to form a via for connection between chips. Particularly, a technology of forming a deep via having a depth of more than about 100 μm is required to connect chips. Currently, a copper (Cu)-plating method is widely used for a gap-fill of a deep via. However, since it is difficult for Cu-ions to diffuse into a deep inner side of a deep via when a gap-fill of a deep via is performed by the Cu-plating method, there are limitations in that a plating rate is very slow and it is difficult to gap-fill the deep via without a void.

### BRIEF SUMMARY

Embodiments provide a semiconductor device and a method for manufacturing the same, which form a deep via penetrating a semiconductor substrate using a silicon nanowire.

Embodiments also provide a System-In-Package (SIP), which forms a deep via in a semiconductor substrate using a silicon nanowire and electrically connects semiconductor chips to each other.

In one embodiment, a semiconductor device comprises: a circuit layer on a semiconductor substrate; a metal interconnection layer on the circuit layer, the metal interconnection layer comprising a metal interconnection connected to the circuit layer; and a deep via through the semiconductor substrate and the metal interconnection layer, the deep via comprising a laser-annealed crystalline silicon.

In another embodiment, a system-in-package comprises: a first semiconductor chip comprising a circuit layer on a silicon substrate, a metal interconnection layer on the circuit layer, the metal interconnection layer comprising a metal interconnection connected to the circuit layer, a deep via through the silicon substrate and the metal interconnection layer, the deep via comprising a laser-annealed crystalline silicon, and a pad on the metal interconnection layer, the pad being electrically connected to the deep via; a first conductive bump contacting one end of the first semiconductor chip; and a second semiconductor chip connected to the first conductive bump.

In still another embodiment, a method for manufacturing a semiconductor device comprises: forming a circuit layer on a semiconductor substrate; forming a metal interconnection layer on the circuit layer, the metal interconnection layer comprising a metal interconnection connected to the circuit layer; forming a deep via hole penetrating a portion of the semiconductor substrate and the metal interconnection layer; gap-filling a silicon nanowire in the deep via hole; and forming a deep via comprising a crystallized silicon by laser-annealing the silicon nanowire in the deep via hole.

The details of one or more embodiments are set forth in the accompanying drawings and the description below. Other features will be apparent from the description and drawings, and from the claims.

### BRIEF DESCRIPTION OF THE DRAWINGS

FIGS. 1 through 11 are cross-sectional views illustrating a process for manufacturing a semiconductor device according to an embodiment.

FIG. 12 is a cross-sectional view illustrating a System-In-Package according to an embodiment.

### DETAILED DESCRIPTION

A system-in-package and a semiconductor device according to embodiments will be described in detail with reference to the accompanying drawings. The invention may, however, be embodied in many different forms and should not be construed as being limited to the embodiments set forth herein; rather, that alternate embodiments included in other retrogressive inventions or falling within the spirit and scope of the present disclosure can easily be derived through adding, altering, and changing, and will fully convey the concept of the invention to those skilled in the art.

In addition, the terms “first” and “second” can be selectively or exchangeably used for the members. In the figures, a dimension of each of elements may be exaggerated for clarity of illustration, and the dimension of each of the elements may be different from an actual dimension of each of the elements. Not all elements illustrated in the drawings must be included and limited to the present disclosure, but the elements except essential features of the present disclosure may be added or deleted. Also, in the descriptions of embodiments, it will be understood that when a layer (or film), a region, a pattern, or a structure is referred to as being “on/above/over/upper” a substrate, layer (or film), region, pad, or patterns, it can be directly on the substrate, layer (or film), region, pad, or patterns, or intervening layers may also be present. Further, it will be understood that when a layer is referred to as being “under/below/lower” a layer (film), region, pattern, or structure, it can be directly under the layer (film), region, pad, or patterns, or one or more intervening layers may also be present. Therefore, meaning thereof should be judged according to the spirit of the present disclosure.

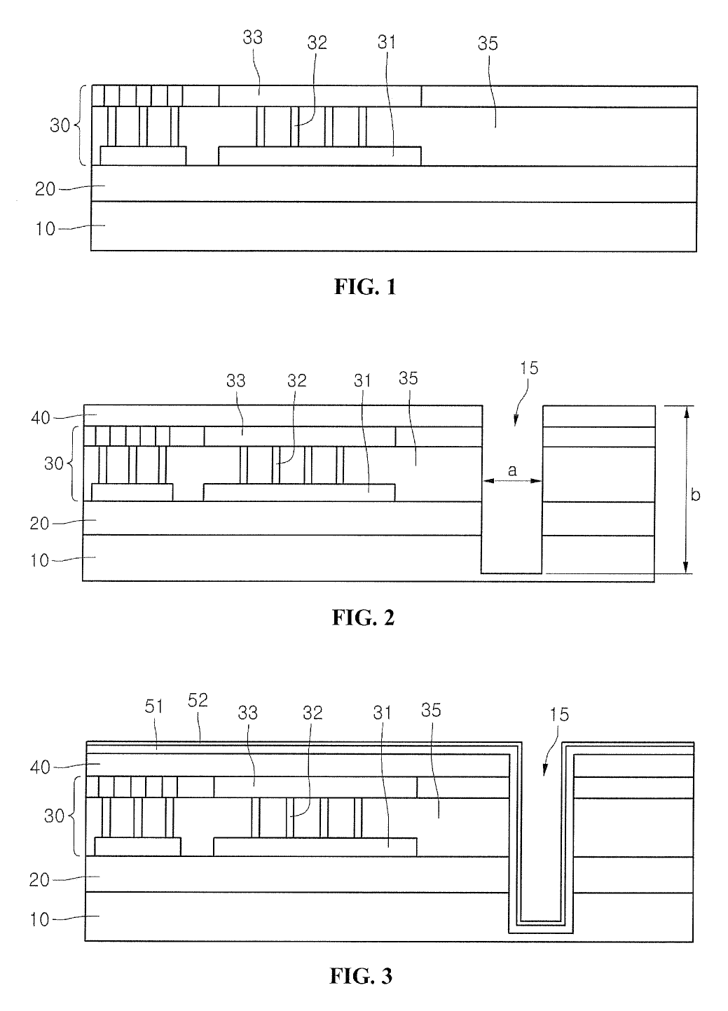

FIGS. 1 through 11 are cross-sectional views illustrating a process for manufacturing a semiconductor device according to an embodiment.

Referring to FIG. 1, a circuit layer 20 including a plurality of transistors is formed on a silicon substrate 10. The circuit layer 20 includes an insulating layer covering the transistors.

The insulating layer may include, for example, Boron Phosphorous Silicate Glass (BPSG) or Tetra-Ethyl-Ortho-Silicate (TEOS).

After the circuit layer 20 is formed, metal interconnections 31, vias 32, and insulating layers 35 covering them are repeatedly formed multiple times to form a metal interconnection layer 30.

When the metal interconnections 31 are formed on different layers, the metal interconnections 31 are electrically connected to each other through a via hole penetrating the insulating layer 35 and a via 32 filling the via hole.

Referring to FIG. 2, after an uppermost metal interconnection 33 is formed on the metal interconnection layer 30, a protection layer 40 is formed over the entire surface of the silicon substrate 10 to cover the metal interconnection layer 30.

The protection layer 40 includes at least one of a silicon oxide and a silicon nitride.

Portions of the protection layer 40, the metal interconnection layer 30, and the silicon substrate 10 are etched through a photolithography process to form a deep via hole 15.

In this case, the width a of the deep via hole 15 ranges from about 5 μm to about 30 μm, and the depth b thereof ranges from about 30 μm to about 100 μm.

Referring to FIG. 3, a first barrier film 51 and a second barrier film 52 are sequentially deposited over the entire surface of the silicon substrate 10 including the deep via hole 15.

The first barrier film 51 may include, for example, an oxide. The thickness of the first barrier film 51 may range from about 1,000 Å to about 5,000 Å. The first barrier film 51 may be formed through a Chemical Vapor Deposition (CVD) process.

The second barrier film 52 may include, for example, a nitride. The thickness of the second barrier film 52 may range from about 500 Å to about 2,000 Å. The second barrier film 52 may be formed through a CVD process.

Accordingly, the first and second barrier films 51 and 52 are formed along the inner wall of the deep via hole 15.

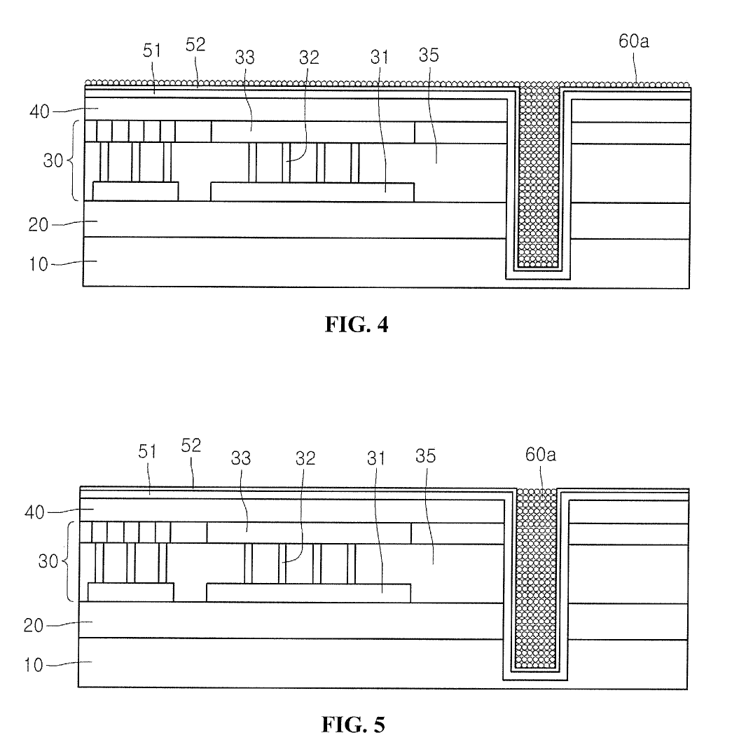

Referring to FIG. 4, a silicon nanowire 60a is grown over the entire surface of the silicon substrate 10 over which the first and second barrier films 51 and 52 are formed.

The silicon nanowire 60a is formed through a CVD process.

First, gold (Au) is thinly deposited over the entire surface of the silicon substrate 10 through a magnetic sputtering method. Then, by introducing a silane gas (SiH₄) into a chamber, a silicon nanowire 60a can be deposited on the entire surface of the second barrier film 52 through catalysis of Au. In this case, the Au serves only as a catalyst, and is not included in the layer.

The Au is formed on an anodic nano-hole channel alumina template, and thus a silicon nanowire may be grown in the shape of a hexagonal honeycomb nano-hole.

Thus, a gap-fill of the deep via hole 15 is achieved, and the silicon nanowire 60a is formed over the entire surface of the silicon substrate 10.

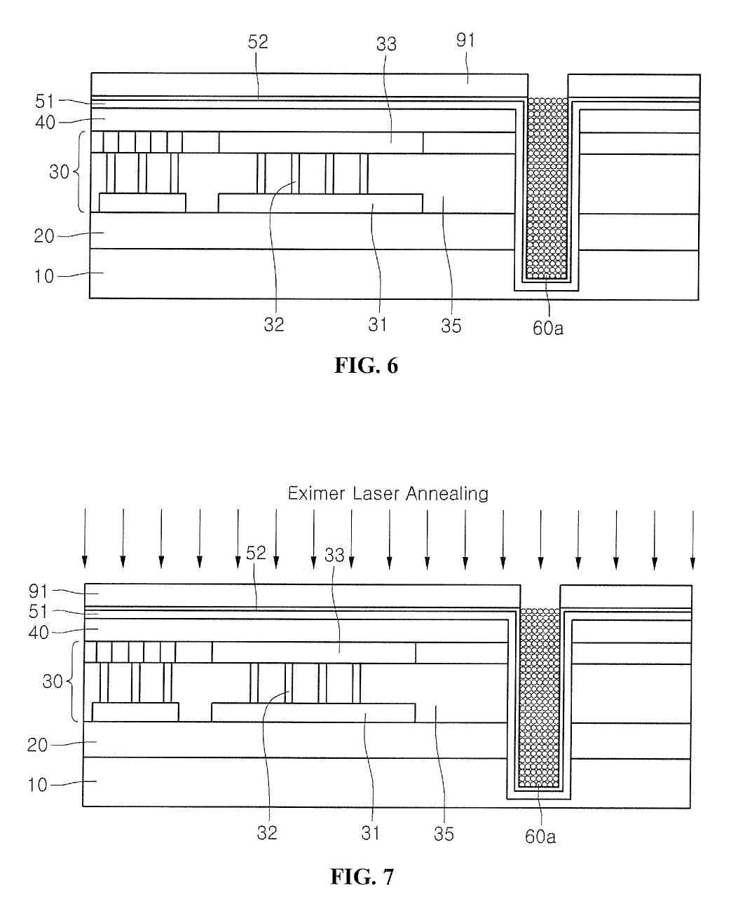

Next, referring to FIG. 5, the silicon nanowire 60a on the second barrier film 52 is removed by an etch-back using a dry etching or a wet etching to isolate the silicon nanowire 60a gap-filled in the deep via hole 15.

That is, the silicon nanowire 60a is removed from the first and second barrier films 51 and 52 on the protection layer 40 to leave the silicon nanowire 60a only in the deep via hole 15 and expose the second barrier film 52 above the protection layer.

Thus, a short between the deep vias can be inhibited, and process reliability can be secured.

Next, referring to FIG. 6, a mask 91 is formed on the exposed second barrier film 52 to selectively expose only the deep via hole 15.

The mask 91 may include, for example, a photoresist pattern.

The mask 91 exposes the silicon nanowire 60a gap-filled in the deep via hole 15.

Referring to FIG. 7, a laser annealing is performed on the mask 91.

The laser annealing may be performed using an excimer laser. The wavelength of the laser may range from about 1,000 nm to about 1,500 nm. The laser annealing may be performed for about 1 nanosecond to about 99 seconds. Also, the laser energy may be applied at a rate of about 2 J/cm² to about 10 J/cm².

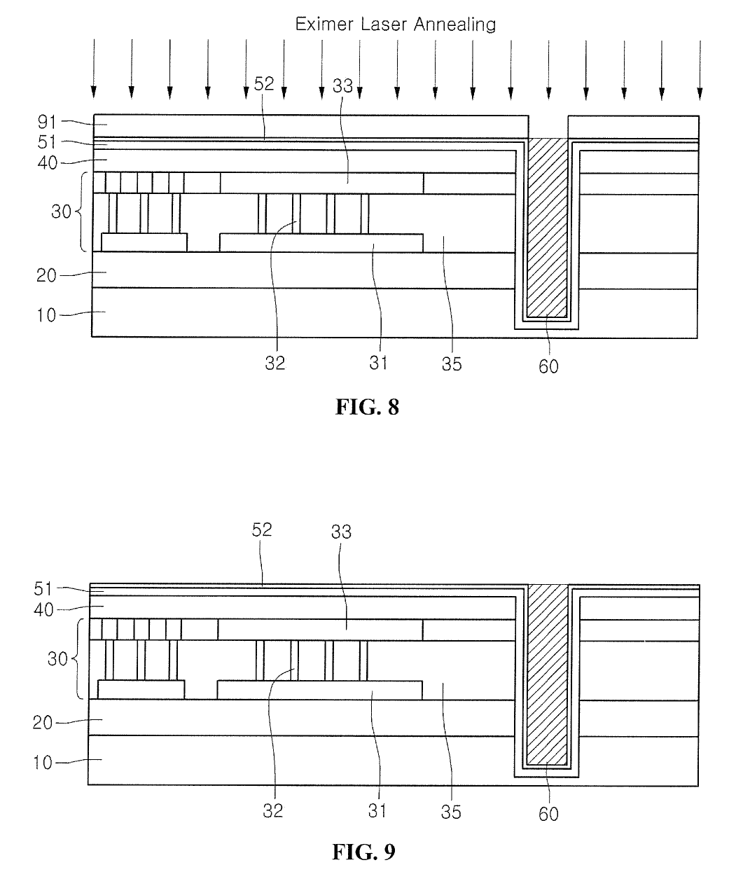

Thus, the silicon nanowire 60a in the deep via hole 15 exposed by the mask 91 is crystallized by the laser to form a deep via 60 as shown in FIG. 8.

The deep via 60 has a polysilicon crystal shape and conductivity.

Referring to FIG. 9, the mask 91 is removed to expose the second barrier film 52.

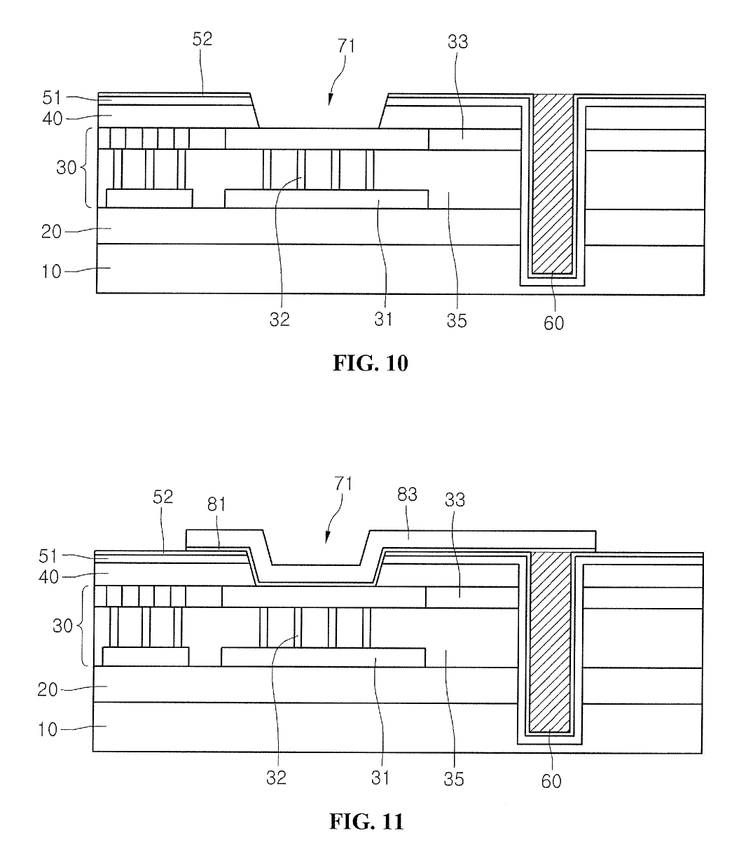

Referring to FIG. 10, the second barrier film 52, the first barrier film 51, and the protection layer 40 are etched to from a terminal via 71 exposing a portion of the uppermost metal interconnection 33.

Referring to FIG. 11, a barrier metal pattern 81 and a pad 83 contacting the uppermost metal interconnection 33 exposed by the terminal via 71 may be formed by patterning a barrier metal layer and a metal layer formed on the terminal via 71.

Examples of materials that can be used for the barrier metal layer include titanium (Ti), titanium nitride (TiN), titanium silicon nitride (TiSiN), tantalum (Ta), tantalum nitride (TaN), and tantalum silicon nitride (TaSiN).

Examples of materials that can be used as the metal layer for the pad 83 include aluminum (Al), Al alloy, Ti, TiN, TiSiN, Ta, TaN, and TaSiN.

The barrier metal pattern 81 and the pad 83 are extended along a top surface of the device to the deep via 60, and contact the deep via to be electrically connected.

Next, the rear surface of the silicon substrate 10 is etched to expose one end of the deep via 60. In this case, a portion of the first and second barrier films 51 and 52 formed at one end of the deep via 60 may be etched to expose the deep via 60. The second barrier film 52 may be formed to cover the deep via 60 at the one end, and the first barrier film 51 may be formed to cover the second barrier film 52. These films can be etched to expose the one end of the via while remaining at the sidewalls of the deep via.

The thickness H of the silicon substrate 10 left after the etching of the rear surface of the silicon substrate 10 may range from about 40 μm to about 100 μm.

Many electrical signals are applied to the deep via 60, and thus a large amount of heat is generated in the deep via 60. Since the deep via 60 is formed of the same material as the silicon substrate 10, their Coefficient of Thermal Expansion (CTE) characteristics are excellent. Accordingly, limitations such as cracks caused by heat expansion around the deep via 60 can be solved, thereby improving product reliability.

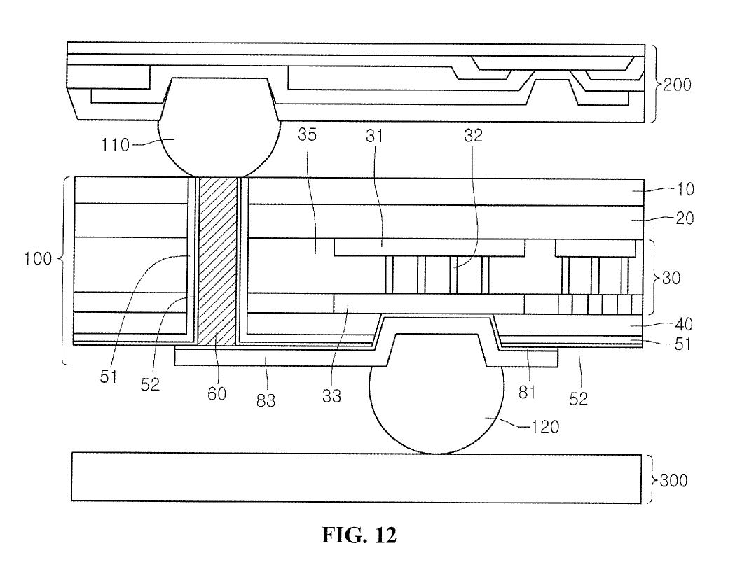

FIG. 12 is a cross-sectional view illustrating a SIP according to an embodiment.

Referring to FIG. 12, the SIP according to an embodiment includes a first semiconductor chip 100 manufactured according to the process of FIGS. 1 through 11 and a second semiconductor chip 200 stacked on the first semiconductor chip 100.

The first semiconductor chip 100 is manufactured to have the structure as described above.

The second semiconductor chip 200 is electrically connected to the first semiconductor chip 100.

The second semiconductor chip 200 includes a circuit layer including transistors on a semiconductor substrate, a metal interconnection layer including metal interconnections connected to the circuit layer, and pads formed on the metal interconnection layer. The pads may exchange electrical signals with the metal interconnection of the metal interconnection layer and the circuit layers.

One end of the deep via 60 of the first semiconductor chip 100 is electrically connected to the pad of the second semiconductor chip 200 through a first conductive bump 110.

The one end of the deep via 60 may be an end portion formed on the front surface of the silicon substrate 10, or may be an end portion formed on the rear surface of the silicon substrate 10.

Thereafter, the first semiconductor chip 100 is mounted onto a Printed Circuit Board (PCB) 300.

The pad 83 of the first semiconductor chip 100 is electrically connected to the PDB 300 through a second conductive bump 120 interposed between the first semiconductor chip 100 and the PCB 300.

The pad 83 of the first semiconductor chip 100 is electrically connected to the deep via 60.

Accordingly, the first semiconductor chip 100, the second semiconductor chip 200, and the PCB 300 may operate while exchanging electrical signals with each other.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A semiconductor device comprising:
a circuit layer on a semiconductor substrate;
a metal interconnection layer on the circuit layer, the metal interconnection layer comprising a metal interconnection connected to the circuit layer; and
a deep via through the semiconductor substrate and the metal interconnection layer, the deep via comprising a laser-annealed crystalline silicon.

2. The semiconductor device according to claim 1, wherein the deep via has a width of about 5 μm to about 30 μm and a depth of about 30 μm to about 100 μm.

3. The semiconductor device according to claim 1, further comprising a pad on the metal interconnection layer, the pad being electrically connected to the deep via.

4. The semiconductor device according to claim 1, further comprising a second barrier film covering sidewalls of the deep via and a first barrier film covering the second barrier film at the sidewalls of the deep via.

5. The semiconductor device according to claim 4, wherein the first barrier film comprises an oxide, and the second barrier film comprises a nitride.

6. A system-in-package comprising:
a first semiconductor chip comprising:
a circuit layer on a silicon substrate,
a metal interconnection layer on the circuit layer, the metal interconnection layer comprising a metal interconnection connected to the circuit layer,
a deep via through the silicon substrate and the metal interconnection layer, the deep via comprising a laser-annealed crystalline silicon, and
a pad on the metal interconnection layer, the pad being electrically connected to the deep via;
a first conductive bump contacting one end of the first semiconductor chip; and
a second semiconductor chip connected to the first conductive bump.

7. The system-in-package according to claim 6, further comprising:
a printed circuit board; and
a second conductive bump formed on the pad of the first semiconductor chip,
wherein the first semiconductor chip is mounted onto the printed circuit board through the second conductive bump formed on the pad.

8. The system-in-package according to claim 6, wherein the deep via has a width of about 5 μm to about 30 μm and a depth of about 30 μm to about 100 μm.

9. A method for manufacturing a semiconductor device, comprising:
forming a circuit layer on a semiconductor substrate;
forming a metal interconnection layer on the circuit layer, the metal interconnection layer comprising a metal interconnection connected to the circuit layer;
forming a deep via hole penetrating a portion of the semiconductor substrate and the metal interconnection layer;
gap-filling a silicon nanowire in the deep via hole; and
forming a deep via comprising a crystallized silicon by laser-annealing the silicon nanowire in the deep via hole.

10. The method according to claim 9, wherein the gap-filling of the silicon nanowire comprises:
stacking a silicon nanowire on the metal interconnection layer where the deep via hole is formed, using Au as a catalyst; and
etching back the entire surface of the silicon nanowire to isolate the silicon nanowire in the deep via hole.

11. The method according to claim 9, wherein the laser annealing is performed using an excimer laser.

12. The method according to claim 9, wherein the forming of the deep via is performed using a laser wavelength of about 1,000 nm to about 1,500 nm and a laser energy of about 2 J/cm² to about 10 J/cm².

13. The method according to claim 9, wherein the forming of the deep via comprises forming a mask on the metal interconnection layer, the mask exposing the deep via hole gap-filled with the silicon nanowire.

14. The method according to claim 9, after the forming of the deep via hole, further comprising:
forming a first barrier film on the metal interconnection layer including in the deep via hole; and
forming a second barrier film on the first barrier film.

15. The method according to claim 14, wherein the first barrier film comprises an oxide, and the second barrier film comprises a nitride.

16. The method according to claim 9, wherein the deep via hole has a width of about 5 μm to about 30 μm and a depth of about 30 μm to about 100 μm.

17. The method according to claim 9, after the forming of the deep via, further comprising forming a pad on the metal interconnection layer, the pad being electrically connected to the metal interconnection and the deep via.

18. The method according to claim 9, wherein the gap-filling of the silicon nanowire comprises depositing the silicon nanowire in the deep via hole through a Chemical Vapor Deposition (CVD) process.
